(19) United States
(12) Patent Application Publication
(10) Pub. No.: US 2015/0369467 A1
(43) Pub. Date: Dec. 24, 2015

(54) HEAT DISSIPATION CIRCUIT BOARD AND METHOD FOR PRODUCING SAME

(71) Applicant: SUMITOMO ELECTRIC INDUSTRIES, LTD., Osaka-shi, Osaka (JP)

(72) Inventors: Hirohisa SAITO, Osaka-shi (JP); Kensaku MOTOKI, Osaka-shi (JP)

(73) Assignee: SUMITOMO ELECTRIC INDUSTRIES, LTD., Osaka-shi, Osaka (JP)

(21) Appl. No.: 14/767,349

(22) PCT Filed: Jul. 22, 2014
(86) PCT No.: PCT/JP2014/069320

§ 371 Date: Aug. 12, 2015

(30) Foreign Application Priority Data
Oct. 24, 2013 (JP) 2013-221664

(51) Int. Cl. F21V 29/70; H05K 1/18; H05K 1/11; F21V 7/05; H05K 3/00; H05K 3/46; F21V 21/00; F21V 19/00; H05K 1/02; H05K 3/30

(52) U.S. Cl. CPC F21V 29/70; H05K 1/028; H05K 1/181; H05K 1/0206; H05K 1/115; H05K 3/305; H05K 3/0058; H05K 3/0011; H05K 3/4688; F21V 21/00; F21V 19/0025; F21V 7/05; H05K 2201/10106; H05K 2201/062; F21Y 2101/02

(57) ABSTRACT

A heat dissipation circuit board comprises a printed circuit board including an insulating film disposed at a back surface and one or more land parts disposed at a front surface, one or more electronic components mounted on the one or more land parts, and an adhesive layer stacked on a back surface of the insulating film. The insulating film and the adhesive layer are removed in a first region that covers at least projection regions of the one or more land parts for each of the electronic components, and removed portions of the insulating film and the adhesive layer are filled with a thermally conductive adhesive.

### TECHNICAL FIELD

The present invention relates to a heat dissipation circuit board and a method for producing the heat dissipation circuit board.

### BACKGROUND ART

Examples of electronic components mounted on printed circuit boards include light emitting diodes (LEDs) that generate a large amount of heat during operation. In such printed circuit boards on which electronic components that generate a large amount of heat are mounted, a metal plate for heat dissipation or the like is generally stacked to prevent degradation of functions of electronic components due to heating and damage to circuits.

To further improve the heat dissipation effect of electronic components, there have been proposed, for example, a circuit board in which a metal plate and a printed circuit board are bonded to each other using a thermally conductive adhesive having high thermal conductivity (refer to Japanese Unexamined Patent Application Publication No. 6-232514) and a circuit board in which a conductive pattern is directly formed on a metal plate with a thermally conductive adhesive disposed therebetween (refer to Japanese Unexamined Patent Application Publication No. 9-139580).

### CITATION LIST

### Patent Literature

PTL 1: Japanese Unexamined Patent Application Publication No. 6-232514

PTL 2: Japanese Unexamined Patent Application Publication No. 9-139580

### SUMMARY OF INVENTION

### Technical Problem

The circuit board in which a metal plate and a printed circuit board are bonded to each other using a thermally conductive adhesive does not produce a sufficient heat dissipation effect because an insulating film is present between the metal plate and the electronic component (conductive pattern). Therefore, when such a circuit board is used as a circuit board for recently widespread LED lighting devices including a plurality of LEDs, the operation conditions are restricted.

In the circuit board in which a conductive pattern is formed on a metal plate with a thermally conductive adhesive disposed therebetween, for example, when the circuit board is curved, the cured thermally conductive adhesive raptures, which degrades the insulating property.

Accordingly, there are provided a heat dissipation circuit board that has high insulation reliability and can effectively facilitate heat dissipation of electronic components and a method for producing the heat dissipation circuit board.

### Solution to Problem

In order to solve the above problems, a heat dissipation circuit board according to one embodiment of the present invention includes a printed circuit board including an insulating film disposed at a back surface and one or more land parts disposed at a front surface, one or more electronic components mounted on the one or more land parts, and an adhesive layer stacked on a back surface of the insulating film. The insulating film and the adhesive layer are removed in a first region that covers at least projection regions of the one or more land parts for each of the electronic components, and removed portions of the insulating film and the adhesive layer are filled with a thermally conductive adhesive.

In order to solve the above problems, a method for producing a heat dissipation circuit board according to another embodiment of the present invention is a method for producing a heat dissipation circuit board including a printed circuit board including an insulating film disposed at a back surface and one or more land parts disposed at a front surface, one or more electronic components mounted on the one or more land parts, an adhesive layer stacked on a back surface of the insulating film, and a supporting member disposed on a back surface of the adhesive layer. The method includes a step of mounting the one or more electronic components on the one or more land parts; a step of removing the insulating film in a first region that covers at least projection regions of the one or more land parts for each of the electronic components; a step of stacking, on the back surface of the insulating film, the adhesive layer in which at least a portion corresponding to the first region has been removed; a step of filling removed portions of the insulating film and the adhesive layer with a thermally conductive adhesive; and a step of disposing a supporting member on the back surface of the adhesive layer having the removed portion filled with the thermally conductive adhesive.

### Advantageous Effects of Invention

The heat dissipation circuit board according to one embodiment of the present invention and the method for producing the heat dissipation circuit board can provide a circuit board that has high insulation reliability, can effectively facilitate the heat dissipation of electronic components mounted, and is suitably used for LED lighting devices and the like.

### BRIEF DESCRIPTION OF DRAWINGS

FIG. 1 is a schematic sectional view illustrating a heat dissipation circuit board according to an embodiment of the present invention.

FIG. 2 is a schematic sectional view illustrating a modification of the heat dissipation circuit board in FIG. 1.

FIG. 3 is a schematic sectional view illustrating a heat dissipation circuit board according to an embodiment different from those of FIG. 1 and FIG. 2.

FIG. 4A is a schematic sectional view illustrating a method for producing the heat dissipation circuit board in FIG. 3.

FIG. 4B is a schematic sectional view illustrating a step after the step in FIG. 4A in the method for producing the heat dissipation circuit board in FIG. 3.

FIG. 4C is a schematic sectional view illustrating a step after the step in FIG. 4B in the method for producing the heat dissipation circuit board in FIG. 3.

FIG. 4D is a schematic sectional view illustrating a step after the step in FIG. 4C in the method for producing the heat dissipation circuit board in FIG. 3.

FIG. 5 is a schematic sectional view illustrating a heat dissipation circuit board according to an embodiment different from those of FIG. 1, FIG. 2, and FIG. 3.

FIG. 6 is a schematic sectional view illustrating a heat dissipation circuit board according to an embodiment different from those of FIG. 1, FIG. 2, FIG. 3, and FIG. 5.

FIG. 7 is a schematic sectional view illustrating a heat dissipation circuit board according to an embodiment different from those of FIG. 1, FIG. 2, FIG. 3, FIG. 5, and FIG. 6.

FIG. 8 is a schematic sectional view illustrating a heat dissipation circuit board according to an embodiment different from those of FIG. 1, FIG. 2, FIG. 3, FIG. 5, FIG. 6, and FIG. 7.

### DESCRIPTION OF EMBODIMENTS

### Description of Embodiments of the Present Invention

(1) A heat dissipation circuit board according to an embodiment of the present invention includes a printed circuit board including an insulating film disposed at a back surface and one or more land parts disposed at a front surface, one or more electronic components mounted on the one or more land parts, and an adhesive layer stacked on a back surface of the insulating film. The insulating film and the adhesive layer are removed in a first region that covers at least projection regions of the one or more land parts for each of the electronic components, and removed portions of the insulating film and the adhesive layer are filled with a thermally conductive adhesive.

In the heat dissipation circuit board, the insulating film and the adhesive layer are removed in the first region that covers at least the projection regions of the land parts for each of the electronic components, and the removed portions are filled with the thermally conductive adhesive. Therefore, the thermally conductive adhesive is directly stacked on the conductive pattern of the printed circuit board. Accordingly, when the heat dissipation circuit board is stacked on the supporting member such as a metal plate with the adhesive layer and the thermally conductive adhesive disposed therebetween, the conductive pattern and the supporting member such as a metal plate are connected to each other with only the thermally conductive adhesive disposed therebetween. Thus, the heat dissipation effect of the electronic component can be considerably improved.

Herein, the “projection regions of the land parts” mean a part of the projection regions of the land parts or the entire projection regions of the land parts. That is, there may be a region in which heat dissipation is not easily achieved in the projection regions of the land parts depending on the shape and characteristics of electronic components mounted (region in which the heat dissipation effect is not improved even if the electronic component is connected to the supporting member such as a metal plate with the thermally conductive adhesive disposed therebetween). In such a region in which heat dissipation is not easily achieved, the insulating film and the adhesive layer are not necessarily removed. The heat dissipation effect can be produced by removing the insulating film and the adhesive layer in the rest of the projection regions of the land parts and filling the removed portions with the thermally conductive adhesive. That is, the present invention includes a case where the first region does not cover a part of the projection regions of the land parts.

The supporting member also has a role in dissipating heat generated in electronic components or the like, and thus the “supporting member” may also be referred to as a “heat dissipation member”.

(2) The first region preferably overlaps projection regions of the electronic components disposed in the first region, and an area occupied by the first region is preferably twice or less a projection area of the electronic components disposed in the first region. As described above, when the first region overlaps a projection region of an electronic component and the area is less than or equal to the upper limit, the area of the insulating film removed can be minimized, and the heat dissipation effect of the electronic component can be produced with certainty.

(3) The adhesive layer is preferably further removed in a second region that covers the first region. By removing the adhesive layer in the second region larger than the first region in such a manner, the filling with the thermally conductive adhesive can be easily performed, and also the removed region of the insulating film and the removed region of the adhesive layer can be easily aligned with each other.

(4) The printed circuit board preferably has a through-hole in each first region, and at least a portion on the back surface side of the through-hole is also preferably filled with the thermally conductive adhesive. By forming such a through-hole in the printed circuit board, the thermally conductive adhesive can be prevented from leaking out to a region outside the first region during the filling with the thermally conductive adhesive.

(5) The through-hole and a portion above the through-hole are also preferably filled with the thermally conductive adhesive so that the thermally conductive adhesive contacts a back surface of each of the electronic components. By bringing the thermally conductive adhesive into contact with the electronic component using the through-hole in such a manner, the heat dissipation effect of the electronic component can be further improved.

(6) The printed circuit board preferably has flexibility. When the printed circuit board has flexibility as described above, stacking can be easily performed on the supporting member such as a metal plate having a curved surface or the like.

(7) A main component of the insulating film is preferably polyimide, a liquid crystal polymer, a fluororesin, polyethylene terephthalate, or polyethylene naphthalate. By using such a resin for the insulating film, for example, the insulating property of the insulating film can be improved. The “main component” is a component with the highest content and is, for example, a component with a content of 50 mass % or more. The “fluororesin” is a resin in which at least one hydrogen atom that bonds to carbon atoms constituting a repeating unit of a polymer chain is substituted with a fluorine atom or an organic group having a fluorine atom.

(8) The thermally conductive adhesive preferably has a thermal conductivity of 1 W/mK or more. When the thermal conductivity of the thermally conductive adhesive is more than or equal to the lower limit as described above, the heat dissipation effect of the electronic component can be further improved.

(9) Each of the electronic components is preferably a light emitting diode. The heat dissipation circuit board produces a high heat dissipation effect as described above, and thus can be suitably used as an LED circuit board.

(10) When the electronic component is a light emitting diode, a surface of the printed circuit board preferably has a light reflecting function. The heat dissipation circuit board produces a high heat dissipation effect as described above. Therefore, even if a light reflecting function is imparted to the surface of the printed circuit board using a material that inhibits heat dissipation, such as a filler or a paint, the heat dissipation of the light emitting diode can be maintained.

(11) The heat dissipation circuit board preferably includes a supporting member disposed on a back surface of the adhesive layer. B y connecting the supporting member and the conductive pattern with only the thermally conductive adhesive disposed therebetween, the above-described heat dissipation effect can be easily produced with certainty.

(12) The supporting member preferably has a curved surface or a bent surface in a stacking region of the printed circuit board. In the heat dissipation circuit board, the printed circuit board includes an insulating film in a region other than the first region. Therefore, even if the heat dissipation circuit board is, for example, curved along the supporting member, the insulating property is not easily degraded. Thus, the insulation reliability can be maintained even if a supporting member having a curved surface or a bent surface is used, and various shapes can be employed.

(13) A method for producing a heat dissipation circuit board according to an embodiment of the present invention is a method for producing a heat dissipation circuit board including a printed circuit board including an insulating film disposed at a back surface and one or more land parts disposed at a front surface, one or more electronic components mounted on the one or more land parts, an adhesive layer stacked on a back surface of the insulating film, and a supporting member disposed on a back surface of the adhesive layer. The method includes a step of mounting the one or more electronic components on the one or more land parts; a step of removing the insulating film in a first region that covers at least projection regions of the one or more land parts for each of the electronic components; a step of stacking, on the back surface of the insulating film, the adhesive layer in which at least a portion corresponding to the first region has been removed; a step of filling removed portions of the insulating film and the adhesive layer with a thermally conductive adhesive; and a step of disposing a supporting member on the back surface of the adhesive layer having the removed portion filled with the thermally conductive adhesive.

In the method for producing a heat dissipation circuit board, the insulating film and the adhesive layer are removed in the first region that covers at least the projection regions of the land parts for each of the electronic components and the removed portions are filled with the thermally conductive adhesive. Thus, a heat dissipation circuit board in which the conductive pattern of the printed circuit board is connected to the supporting member such as a metal plate with only the thermally conductive adhesive disposed therebetween can be easily produced with certainty. In the heat dissipation circuit board, the heat dissipation effect of the electronic component can be considerably improved.

### Details of Embodiments of the Present Invention

Hereafter, a heat dissipation circuit board and a method for producing a heat dissipation circuit board according to embodiments of the present invention will be described in detail with reference to the attached drawings. In the embodiments of the heat dissipation circuit board, the term “front and back” is used to refer to a case where the front is the electronic component-mounted side in a thickness direction of the heat dissipation circuit board and the back is the side opposite to the electronic component-mounted side. The term “front and back” does not refer to a case where a front and a back defined when the heat dissipation circuit board is actually being used.

### First Embodiment

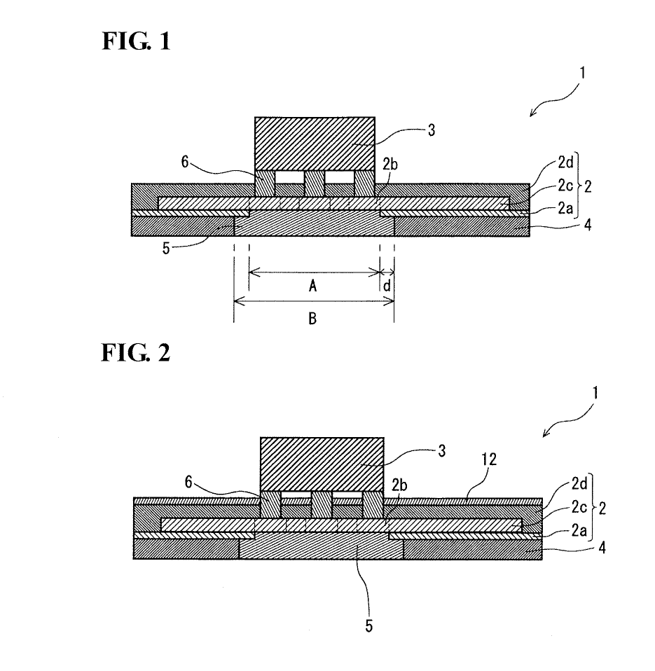

A heat dissipation circuit board 1 illustrated in FIG. 1 mainly includes a flexible printed circuit board 2 including an insulating film (base film) 2a disposed at a back surface and a conductive pattern 2c having a plurality of land parts 2b disposed at a front surface, a light emitting diode 3 mounted on the plurality of land parts 2b, and an adhesive layer 4 stacked on the back surface of the insulating film (base film) 2a. In a first region A that covers at least projection regions of the plurality of land parts 2b for the light emitting diode 3, the insulating film (base film) 2a and the adhesive layer 4 are removed. The removed portions of the insulating film (base film) 2a and the adhesive layer 4 are filled with a thermally conductive adhesive 5.

### <Flexible Printed Circuit Board>

The flexible printed circuit board 2 includes an insulating film (base film) 2a having an insulating property and flexibility, a conductive pattern 2c stacked on the front surface of the insulating film (base film) 2a, and a coverlay 2d stacked on the front surface of the conductive pattern 2c. The conductive pattern 2c includes the plurality of land parts 2b and wiring lines connected to the land parts 2b. A light emitting diode 3 described below is disposed (mounted) on the land parts 2b so as to be electrically connected to the land parts 2b. The conductive pattern 2c may be stacked using an adhesive coated on the front surface of the insulating film (base film) 2a.

### (Insulating Film (Base Film))

The insulating film (base film) 2a included in the flexible printed circuit board 2 is constituted by a plate-shaped member having an insulating property and flexibility. The plate-shaped member constituting the insulating film (base film) 2a may be specifically a resin film. A main component of the resin film is suitably polyimide, a liquid crystal polymer, a fluororesin, polyethylene terephthalate, or polyethylene naphthalate. The insulating film (base film) 2a may contain, a filler, an additive or the like.

The liquid crystal polymer is classified into a thermotropic liquid crystal polymer that exhibits mesomorphism in a molten state and a lyotropic liquid crystal polymer that exhibits mesomorphism in a solution state. In the heat dissipation circuit board according to an embodiment of the present invention, a thermotropic liquid crystal polymer is preferably used.

The liquid crystal polymer is, for example, an aromatic polyester synthesized from an aromatic dicarboxylic acid and a monomer of an aromatic diol or an aromatic hydroxycarboxylic acid. Typical examples of the liquid crystal polymer include a polymer obtained by polymerizing monomers synthesized from parahydroxybenzoic acid (PHB), terephthalic acid, and 4,4′-biphenol and represented by the following formulae (1), (2), and (3); a polymer obtained by polymerizing monomers synthesized from PHB, terephthalic acid, and ethylene glycol and represented by the following formulae (3) and (4); and a polymer obtained by polymerizing monomers synthesized from PHB and 2,6-hydroxynaphthoic acid and represented by the following formulae (2), (3), and (5).

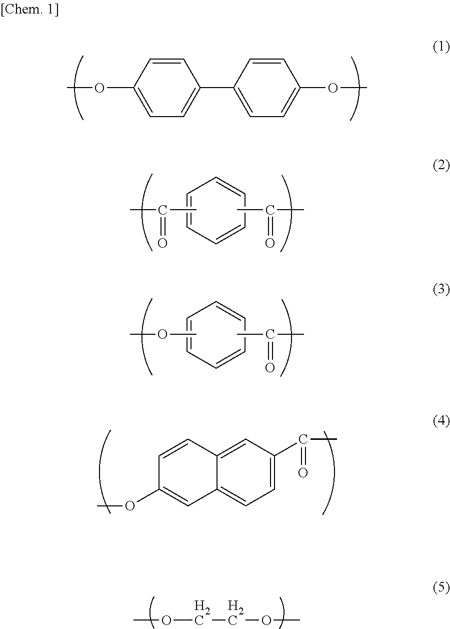

Any liquid crystal polymer that exhibits mesomorphism may be used. The liquid crystal polymer is mainly composed of the above-described polymers (50 mol % or more in the liquid crystal polymer), and other polymers or monomers may be copolymerized. The liquid crystal polymer may also be liquid crystal polyesteramide, liquid crystal polyester ether, liquid crystal polyester carbonate, or liquid crystal polyesterimide.

The liquid crystal polyesteramide is a liquid crystal polyester having an amide bond and is, for example, a polymer obtained by polymerizing monomers represented by the following formula (6) and the above formulae (2) and (4).

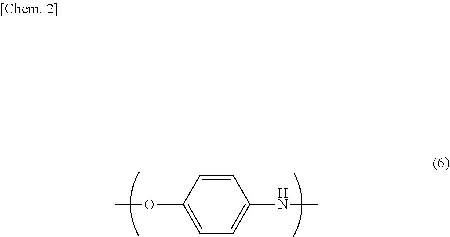

The liquid crystal polymer is preferably produced by subjecting a raw material monomer corresponding to a constituent unit of the liquid crystal polymer to melt polymerization and subjecting the resulting polymer (prepolymer) to solid phase polymerization. Thus, a high-molecular-weight liquid crystal polymer having, for example, high heat resistance, strength, and rigidity can be produced with ease of handling. The melt polymerization may be performed in the presence of a catalyst. Examples of the catalyst include metal compounds such as magnesium acetate, stannous acetate, tetrabutyl titanate, lead acetate, sodium acetate, potassium acetate, and antimony trioxide; and nitrogen-containing heterocyclic compounds such as 4-(dimethylamino)pyridine and 1-methylimidazole. The nitrogen-containing heterocyclic compound is preferably used.

The fluororesin is a resin in which at least one hydrogen atom that bonds to carbon atoms constituting a repeating unit of a polymer chain is substituted with a fluorine atom or an organic group having a fluorine atom (hereafter also referred to as a “fluorine-containing group”). The fluorine-containing group is a group in which at least one hydrogen atom in a linear or branched organic group is substituted with a fluorine atom. Examples of the fluorine-containing group include fluoroalkyl groups, fluoroalkoxy groups, and fluoropolyether groups.

The “fluoroalkyl group” is an alkyl group in which at least one hydrogen atom is substituted with a fluorine atom and includes a “perfluoroalkyl group”. Specifically, the “fluoroalkyl group” includes a group in which all hydrogen atoms in an alkyl group are substituted with fluorine atoms and a group in which all hydrogen atoms other than one hydrogen atom at the terminal of an alkyl group are substituted with fluorine atoms.

The “fluoroalkoxy group” is an alkoxy group in which at least one hydrogen atom is substituted with a fluorine atom and includes a “perfluoroalkoxy group”. Specifically, the “fluoroalkoxy group” includes a group in which all hydrogen atoms in an alkoxy group are substituted with fluorine atoms and a group in which all hydrogen atoms other than one hydrogen atom at the terminal of an alkoxy group are substituted with fluorine atoms.

The “fluoropolyether group” is a monovalent group which has a plurality of alkylene oxide chains as a repeating unit and has an alkyl group or a hydrogen atom at its terminal and in which at least one hydrogen atom in the alkylene oxide chains and/or the alkyl group or hydrogen atom at the terminal is substituted with a fluorine atom. The “fluoropolyether group” includes a “perfluoropolyether group” having a plurality of perfluoroalkylene oxide chains as a repeating unit.

The fluororesin is preferably a tetrafluoroethylene-hexaoropropylene copolymer (FEP), a tetrafluoroethylene-perfluoroalkyl vinyl ether copolymer (PFA), polytetrafluoroethylene (PTFE), polyvinylidene fluoride (PVdF), a fluoroelastomer, a tetrafluoroethylene-hexafluoropropylene-vinylidene fluoride copolymer (THV), or a tetrafluoroethylene-perfluorodioxole copolymer (TFE/PDD).

The lower limit of the average thickness of the insulating film (base film) 2a is preferably 5 μm and more preferably 12 μm. The upper limit of the average thickness of the insulating film (base film) 2a is preferably 50 μm and more preferably 25 μm. If the average thickness of the insulating film (base film) 2a is less than the lower limit, the insulating film (base film 2a) may have insufficient strength. If the average thickness of the insulating film (base film) 2a is more than the upper limit, the flexibility of the flexible printed circuit board 2 may be impaired.

The insulating film (base film) 2a has a cavity (removed portion) in the first region A that covers at least the projection regions of the plurality of land parts 2b, and the cavity is filled with a thermally conductive adhesive 5 described below. The first region A is a continuous region that includes the plurality of land parts 2b and overlaps the projection region of the light emitting diode 3.

In FIG. 1, the first region A covers the entire projection regions of the plurality of land parts 2b. That is, the projection regions of the plurality of land parts 2b are completely included in the first region A. Herein, a part of the projection regions of the land parts 2b is not necessarily included in the first region A as long as the heat dissipation effect is improved. In a projection region of one of the land parts 2b, the lower limit of the area fraction of a region of the land part 2b covered by the first region A relative to the entire projection region of the land part 2b is preferably 80%, more preferably 90%, and further preferably 95%. If the area fraction is less than the lower limit, the heat dissipation circuit board 1 may produce an insufficient heat dissipation effect.

The upper limit of the area occupied by the first region A is preferably twice, more preferably 1.8 times, and further preferably 1.5 times the projection area of the light emitting diode 3. If the area occupied by the first region A is more than the upper limit, the removed region of the insulating film (base film) 2a is increased. Consequently, when the heat dissipation circuit board 1 is stacked on a bent surface or the like, an effect of preventing a decrease in insulation reliability may be insufficiently produced.

### (Conductive Pattern)

The conductive pattern 2c includes the plurality of land parts 2b and wiring lines connected to the land parts 2b, and is formed in a desired planar shape (pattern) by etching a metal layer stacked on the front surface of the insulating film (base film) 2a. The land parts 2b are sites to which the terminal of the light emitting diode 3 is connected. A wiring portion is formed so that the plurality of land parts 2b are connected to each other.

The conductive pattern 2c can be formed of a conductive material. The conductive pattern 2c is generally formed of, for example, copper.

The lower limit of the average thickness of the conductive pattern 2c is preferably 5 μm and more preferably 8 μm. The upper limit of the average thickness of the conductive pattern 2c is preferably 50 μm and more preferably 35 μm. If the average thickness of the conductive pattern 2c is less than the lower limit, the conductivity may be insufficient. If the average thickness of the conductive pattern 2c is more than the upper limit, the flexibility of the flexible printed circuit board 2 may be impaired.

### (Coverlay)

A coverlay 2d is stacked in a portion other than a portion (the front surface side of the land parts 2b) on the front surface of the flexible printed circuit board 2 on which the light emitting diode 3 is mounted. The coverlay 2d has an insulating function and an adhesive function, and is bonded to the front surfaces of the insulating film (base film) 2a and the conductive pattern 2c. When the coverlay 2d includes an insulating layer and an adhesive layer, the insulating layer may be composed of the same material as the insulating film (base film) 2a. The average thickness of the insulating layer may be the same as that of the insulating film (base film) 2a. An adhesive used for the adhesive layer of the coverlay 2d is, for example, suitably an epoxy adhesive. The average thickness of the adhesive layer is not particularly limited, but is preferably 12.5 μm or more and 60 μm or less.

The coverlay 2d is preferably colored with white. When the coverlay 2d is colored with white, a light reflecting function of reflecting light emitted from the light emitting diode 3 to the flexible printed circuit board 2 and increasing the utilization efficiency of the light can be imparted to the front surface of the flexible printed circuit board 2. Furthermore, when the coverlay 2d is colored with white, the design of the heat dissipation circuit board 1 can be improved. The coverlay 2d can be colored with white by, for example, adding a white pigment. Examples of the white pigment include titanium oxide, barium sulfate, aluminum oxide, calcium carbonate, zinc oxide, and silicon oxide.

Instead of using the white coverlay 2d, a coat layer 12 may be stacked on the front surface of the coverlay 2d as illustrated in FIG. 2. The coat layer 12 can be formed of a resin containing a white pigment. The coverlay 2d or the coat layer 12 may be colored with silver or the like instead of white.

When the front surface of the flexible printed circuit board 2 has a light reflecting function as described above, the lower limit of the light reflectance of the surface is preferably 75% and more preferably 80%. The light reflectance is a light reflectance measured in conformity with JIS-K 7375 (2008) using light having a wavelength of 550 nm.

### <Light Emitting Diode>

The light emitting diode 3 is mounted on the land parts 2b of the flexible printed circuit board 2. The light emitting diode 3 may be a multicolor emission type or single-color emission type light emitting diode, and may also be a chip type light emitting diode or a surface-mount light emitting diode packaged with a synthetic resin or the like. The light emitting diode 3 is connected to the land parts 2b through a solder 6. However, the method for connecting the light emitting diode 3 to the land parts 2b is not limited to the soldering, and may be, for example, die bonding that uses a conductive paste or wire bonding that uses a metal wire.

### <Adhesive Layer>

The adhesive layer 4 is a layer mainly made of an adhesive capable of bonding the insulating film (base film) 2a to a supporting member such as a metal plate. The adhesive is not particularly limited, and may be, for example, a heat-curable adhesive such as an epoxy adhesive, a silicone adhesive, or an acrylic adhesive. The adhesive layer 4 may optionally contain an additive. Herein, the heat dissipation circuit board 1 includes a thermally conductive adhesive 5 described below, and therefore there is no need to impart thermal conductivity to the adhesive layer 4.

The lower limit of the average thickness of the adhesive layer 4 is preferably 5 μm and more preferably 10 μm. The upper limit of the average thickness of the adhesive layer 4 is preferably 50 μm and more preferably 25 μm. If the average thickness of the adhesive layer 4 is less than the lower limit, the adhesive strength between the heat dissipation circuit board 1 and the supporting member such as a metal plate may be insufficiently low. If the average thickness of the adhesive layer 4 is more than the upper limit, the thickness of the heat dissipation circuit board 1 may be unnecessarily increased or the distance between the conductive pattern 2c and the supporting member such as a metal plate is increased, which may result in insufficient heat dissipation.

The adhesive layer 4 has a cavity (removed portion) in the first region A (the region that covers at least the projection regions of the plurality of land parts 2b) and a second region B that covers the first region A, and the cavity is filled with a thermally conductive adhesive 5 described below. The second region B is a continuous region that includes the plurality of land parts 2b as in the first region A. The second region B overlaps the projection region of the light emitting diode 3 and has an occupation area larger than that of the first region A. By removing the adhesive layer 4 in the second region B larger than the first region A in such a manner, the cavity can be easily filled with a thermally conductive adhesive 5 described below. When the adhesive layer 4 having a portion removed in the second region B is stacked on the insulating film (base film) 2a having a portion removed in the first region A, these regions are easily aligned with each other.

The lower limit of the minimum distance d between the boundary of the second region B and the boundary of the first region A is preferably 1 μm, more preferably 10 μm, further preferably 20 μm, and particularly preferably 50 μm. The upper limit of the minimum distance d between the boundary of the second region B and the boundary of the first region A is preferably 500 μm, more preferably 300 μm, and further preferably 100 μm. If the minimum distance d is less than the lower limit, it may be insufficiently achieved to easily fill the cavity with the thermally conductive adhesive 5. If the minimum distance d is more than the upper limit, the amount of the thermally conductive adhesive 5 used for the filling is increased, and thus the cost of the heat dissipation circuit board 1 is unnecessarily increased.

### <Thermally Conductive Adhesive>

The removed portion of the insulating film (base film) 2a in the first region A and the removed portion of the adhesive layer 4 in the second region B are filled with a thermally conductive adhesive 5 so that the thermally conductive adhesive 5 contacts the back surface of the conductive pattern 2c including the plurality of land parts 2b.

The thermally conductive adhesive 5 contains a thermosetting resin and a thermally conductive filler. Examples of the thermosetting resin include epoxy, phenolic resin, and polyimide. Among them, epoxy is preferred because it has a good joining force for the thermally conductive filler. Among the epoxy resins, bisphenol A epoxy or bisphenol F epoxy having good liquidity is preferably used in view of the mixing property of the thermally conductive filler.

The thermally conductive filler may be, for example, a metal oxide or a metal nitride. Examples of the metal oxide include aluminum oxide, silicon oxide, beryllium oxide, and magnesium oxide. Among them, aluminum oxide is preferably used in terms of an electrically insulating property, thermal conductivity, and cost. Examples of the metal nitride include aluminum nitride, silicon nitride, and boron nitride. Among them, boron nitride is preferably used in terms of an electrically insulating property, thermal conductivity, and low dielectric constant. The metal oxide and the metal nitride can be used in combination of two or more.

The lower limit of the content of the thermally conductive filler in the thermally conductive adhesive 5 is preferably 40 vol % and more preferably 45 vol %. The upper limit of the content of the thermally conductive filler is preferably 85 vol % and more preferably 80 vol %. If the content of the thermally conductive filler is less than the lower limit, the thermal conductivity of the thermally conductive adhesive 5 may be insufficiently low. If the content of the thermally conductive filler is more than the upper limit, air bubbles are easily contained when the thermosetting resin and the thermally conductive filler are mixed with each other, which may decrease the withstanding voltage. The thermally conductive adhesive 5 may contain an additive such as a curing agent, in addition to the thermally conductive filler.

The lower limit of the thermal conductivity of the thermally conductive adhesive 5 is preferably 1 W/mK and more preferably 3 W/mK. The upper limit of the thermal conductivity of the thermally conductive adhesive 5 is preferably 20 W/mK. If the thermal conductivity of the thermally conductive adhesive 5 is less than the lower limit, the heat dissipation effect of the heat dissipation circuit board 1 may be insufficient. If the thermal conductivity of the thermally conductive adhesive 5 is more than the upper limit, the content of the thermally conductive filler is excessively increased. Consequently, air bubbles are easily contained when the thermosetting resin and the thermally conductive filler are mixed with each other, which may decrease the withstanding voltage and may excessively increase the cost.

The thermally conductive adhesive 5 preferably has a good insulating property. Specifically, the lower limit of the volume resistivity of the thermally conductive adhesive 5 is preferably 1×10⁸ Ωcm and more preferably 1×10¹⁰ Ωcm. If the volume resistivity of the thermally conductive adhesive 5 is less than the lower limit, the insulating property of the thermally conductive adhesive 5 degrades. Consequently, the conductive pattern 2c may have electrical conduction with the supporting member such as a metal plate stacked on the back surface of the insulating film (base film) 2a. The volume resistivity is a value measured in conformity with JIS-C 2139 (2008).

The average thickness of the thermally conductive adhesive 5 (the average distance from the back surface of the thermally conductive adhesive 5 to the back surface of the conductive pattern 2c) is preferably larger than the sum of the average thickness of the insulating film (base film) 2a and the average thickness of the adhesive layer 4. Specifically, the lower limit of the average thickness of the thermally conductive adhesive 5 is preferably 10 μm and more preferably 20 μm. The upper limit of the average thickness of the thermally conductive adhesive 5 is preferably 100 μm and more preferably 50 μm. If the average thickness of the thermally conductive adhesive 5 is less than the lower limit, the thermally conductive adhesive 5 does not contact the supporting member (e.g., metal plate) disposed (stacked) on the back surface of the insulating film (base film) 2a, and thus the heat dissipation effect may be insufficient. If the average thickness of the thermally conductive adhesive 5 is more than the upper limit, the amount of the thermally conductive adhesive 5 used for the filling is increased, which may increase the cost and may unnecessarily increase the thickness of the heat dissipation circuit board 1.

### <Advantage>

In the heat dissipation circuit board 1, the insulating film (base film) 2a and the adhesive layer 4 are removed in the first region A that covers at least the projection regions of the land parts 2b on which the light emitting diode 3 is mounted, and the removed portions are filled with the thermally conductive adhesive 5. Therefore, the thermally conductive adhesive 5 is directly stacked on the conductive pattern 2c of the flexible printed circuit board 2. Accordingly, when the heat dissipation circuit board 1 is stacked on the supporting member such as a metal plate with the adhesive layer 4 and the thermally conductive adhesive 5 disposed therebetween, the conductive pattern 2c and the supporting member such as a metal plate are connected to each other with only the thermally conductive adhesive 5 disposed therebetween. Thus, the heat dissipation effect of the light emitting diode 3 electrically connected to the conductive pattern 2c can be considerably improved.

The adhesive layer 4 is further removed in the second region B that covers the first region A. Therefore, in the heat dissipation circuit board 1, the filling with the thermally conductive adhesive 5 can be easily performed, and also the removed region of the insulating film (base film) 2a and the removed region of the adhesive layer 4 can be easily aligned with each other.

The heat dissipation circuit board 1 includes the flexible printed circuit board 2, and therefore can be easily stacked on the supporting member such as a metal plate having a curved surface or the like.

The heat dissipation circuit board 1 may includes a release film on the back surface of the adhesive layer 4. The release film may be obtained by subjecting the surface of a resin film to a release treatment. The release film is detached when the heat dissipation circuit board 1 is bonded to the supporting member such as a metal plate.

### Second Embodiment

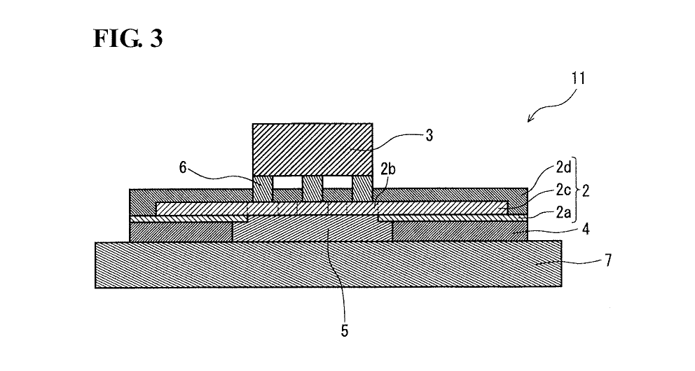

A heat dissipation circuit board 11 illustrated in FIG. 3 mainly includes a flexible printed circuit board 2 including an insulating film (base film) 2a disposed at a back surface and a conductive pattern 2c having a plurality of land parts 2b and disposed at a front surface, a light emitting diode 3 mounted on the plurality of land parts 2b, an adhesive layer 4 stacked on the back surface of the insulating film (base film) 2a, and a supporting member (metal plate) 7 disposed (stacked) on the back surface of the adhesive layer 4. In a first region A that covers at least projection regions of the plurality of land parts 2b for the light emitting diode 3, the insulating film (base film) 2a and the adhesive layer 4 are removed. The removed portions of the insulating film (base film) 2a and the adhesive layer 4 are filled with a thermally conductive adhesive 5. The flexible printed circuit board 2, the light emitting diode 3, the adhesive layer 4, and the thermally conductive adhesive 5 are the same as those included in the heat dissipation circuit board 1 according to the first embodiment, and therefore the same reference numerals are given to omit the description.

### <Supporting Member (Metal Plate)>

The supporting member is preferably a metal plate. The supporting member (metal plate) 7 is a plate-shaped member made of a metal. The supporting member (metal plate) 7 may be made of a metal such as aluminum, magnesium, copper, iron, nickel, molybdenum, or tungsten. Among them, aluminum is particularly preferred because aluminum has good thermal conductivity, good workability, and light weight.

The lower limit of the average thickness of the supporting member (metal plate) 7 is preferably 0.3 mm and more preferably 0.5 mm. The upper limit of the average thickness of the supporting member (metal plate) 7 is preferably 5 mm and more preferably 3 mm. If the average thickness of the supporting member (metal plate) 7 is less than the lower limit, the strength of the supporting member (metal plate) 7 may be insufficiently low. If the average thickness of the supporting member (metal plate) 7 is more than the upper limit, it may be difficult to process the supporting member (metal plate) 7. Furthermore, the weight and volume of the heat dissipation circuit board 11 may be unnecessarily increased.

### [Method for Producing Heat Dissipation Circuit Board]

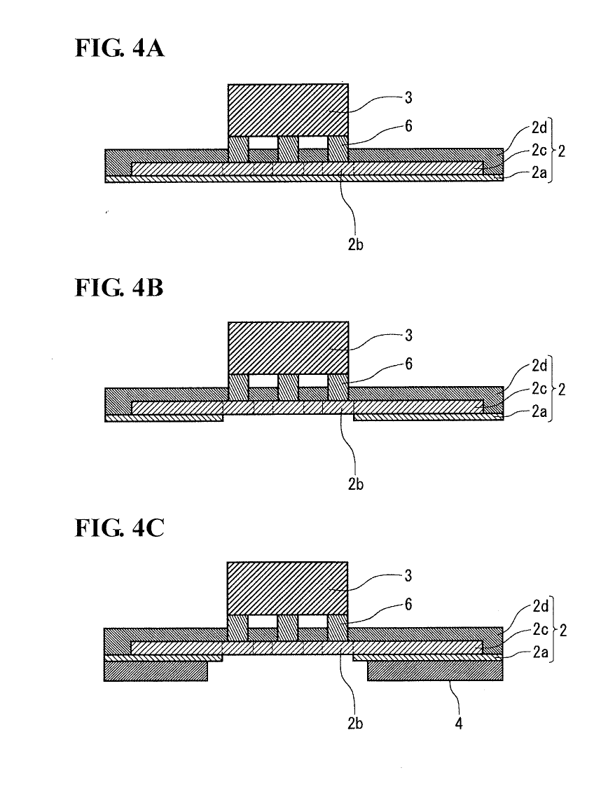

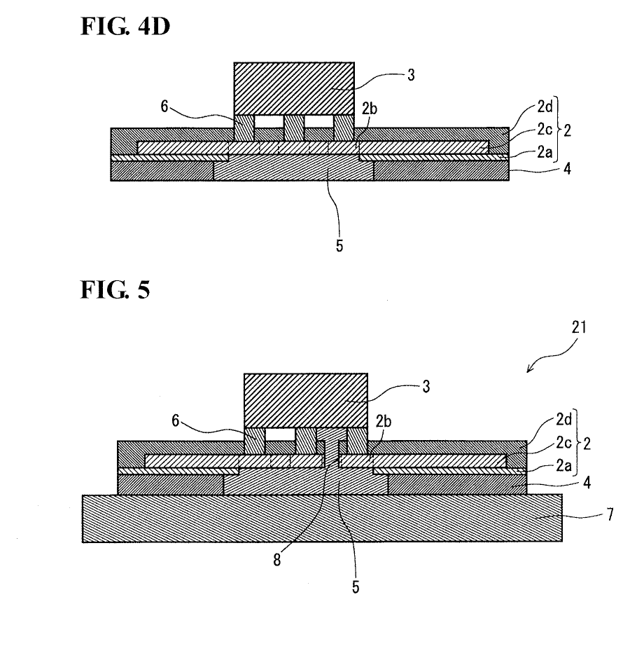

As illustrated in FIG. 4, the heat dissipation circuit board 11 can be produced by, for example, a production method including a step of mounting a light emitting diode 3 on a plurality of land parts 2b of the flexible printed circuit board 2; a step of removing an insulating film (base film) 2a in a first region A that covers at least projection regions of the plurality of land parts 2b for the light emitting diode 3; a step of stacking, on the back surface of the insulating film (base film) 2a, an adhesive layer 4 in which a portion corresponding to a second region B that covers the first region A has been removed; a step of filling the removed portions of the insulating film (base film) 2a and the adhesive layer 4 with a thermally conductive adhesive 5; and a step of disposing (stacking) a supporting member (metal plate) 7 on the back surface of the adhesive layer 4 having the removed portion filled with the thermally conductive adhesive 5.

### (Light Emitting Diode-Mounting Step)

In the light emitting diode-mounting step, as illustrated in FIG. 4A, a plurality of terminals of a light emitting diode 3 are connected to a plurality of land parts 2b of a flexible printed circuit board 2 to mount the light emitting diode 3 on the flexible printed circuit board 2. The light emitting diode 3 can be connected to the land parts 2b by, for example, reflow soldering, die bonding that uses a conductive paste, or wire bonding that uses a metal wire. FIG. 4A illustrates an example in which the light emitting diode 3 is mounted using a solder 6.

### (Insulating Film (Base Film)-Removing Step)

In the insulating film (base film)-removing step, as illustrated in FIG. 4B, an insulating film (base film) 2a is removed in a first region A that covers at least projection regions of the plurality of land parts 2b for the light emitting diode 3. Examples of a method for removing the insulating film (base film) 2a include a method in which a region other than the first region A is masked and then dipping is performed using an etching solution, a method in which a region other than the first region A is masked and then plasma etching is performed, and a method in which the first region A is irradiated with laser beams. Although the insulating film (base film)-removing step is performed after the light emitting diode-mounting step, the insulating film (base film)-removing step may be performed before the light emitting diode-mounting step.

### (Adhesive Layer-Stacking Step)

In the adhesive layer-stacking step, as illustrated in FIG. 4C, an adhesive layer 4 in which a portion corresponding to a second region B that covers the first region A has been removed is stacked on the insulating film (base film) 2a. This step can be performed by, for example, the following procedure. First, an adhesive sheet is prepared which includes a release film, an adhesive in a B-stage state (semi-cured state) stacked on the surface of the release film by performing coating, and another release film stacked on the surface of the adhesive. Next, a portion corresponding to the second region B of the adhesive sheet is removed by performing punching or the like together with the release films. Subsequently, one of the release films of the adhesive sheet is detached. The adhesive sheet is stacked (temporarily bonded) on the insulating film (base film) 2a so that the removed portion (the portion corresponding to the second region B) of the adhesive sheet covers the removed region of the insulating film (base film) 2a and the adhesive-exposed surface of the adhesive sheet faces the back surface of the insulating film (base film) 2a. The portion corresponding to the second region B may be removed after the adhesive sheet is stacked on the insulating film (base film) 2a, however, the punching cannot be employed and therefore the above-described method is preferably used because better workability is achieved.

### (Thermally Conductive Adhesive-Filling Step)

In the thermally conductive adhesive-filling step, as illustrated in FIG. 4D, the removed portions of the insulating film (base film) 2a and the adhesive layer 4 are filled with a thermally conductive adhesive 5. Examples of a method in which the removed portions are filled with the thermally conductive adhesive 5 include a method in which the thermally conductive adhesive 5 is printed by screen printing, a method in which the thermally conductive adhesive 5 is ejected using a dispenser, and a method in which an adhesive sheet including a release film and the thermally conductive adhesive 5 stacked on the release film is attached. The order of the adhesive layer-stacking step and the thermally conductive adhesive-filling step may be changed.

### (Supporting Member (Metal Plate)-Disposing Step)

In the supporting member (metal plate)-disposing step, a supporting member (metal plate) 7 is disposed (stacked) on the back surface of the flexible printed circuit board 2 in which the adhesive layer 4 has been stacked on the back surface and the removed portions of the insulating film (base film) 2a and the adhesive layer 4 have been filled with the thermally conductive adhesive 5. Specifically, the release film on the back surface side (the side opposite to the flexible printed circuit board 2) of the adhesive sheet is detached, and the flexible printed circuit board 2 is stacked (temporarily bonded) on the supporting member (metal plate) 7 to obtain a layered body. Subsequently, the layered body is compressed at a relatively low temperature in, for example, a vacuum container to perform temporary compression bonding. After the temporary compression bonding, the layered body is heated at a high temperature to cure the adhesives. Thus, the heat dissipation circuit board 11 is obtained. This step has been called a “supporting member (metal plate)-disposing step”, but may be called a “supporting member (metal plate)-stacking step”.

The pressure at which the layered body is subjected to the temporary compression bonding may be, for example, 0.05 MPa or more and 1 MPa or less. The temperature during the temporary compression bonding is preferably, for example, 70° C. or more and 120° C. or less. The lower limit of the viscosity of the thermally conductive adhesive 5 during the temporary compression bonding is preferably 100 Pa·s and more preferably 500 Pa·s. The upper limit of the viscosity of the thermally conductive adhesive 5 during the temporary compression bonding is preferably 10000 Pa·s and more preferably 5000 Pa·s. If the viscosity of the thermally conductive adhesive 5 during the temporary compression bonding is less than the lower limit, the thermally conductive adhesive 5 flows before being cured, and thus the filling state of the thermally conductive adhesive 5 may degrade. If the viscosity of the thermally conductive adhesive 5 during the temporary compression bonding is more than the upper limit, the removed portions of the insulating film (base film) 2a and the adhesive layer 4 may be insufficiently filled with the thermally conductive adhesive 5.

The temperature of the layered body during the high-temperature heating may be, for example, 120° C. or more and 200° C. or less. The high-temperature heating time may be, for example, 30 minutes or more and 300 minutes or less and preferably 30 minutes or more and 120 minutes or less.

### <Advantage>

In the heat dissipation circuit board 11, the conductive pattern 2c and the supporting member (metal plate) 7 are connected to each other with only the thermally conductive adhesive 5 disposed therebetween. Therefore, the heat dissipation effect of the light emitting diode 3 having conductivity with the conductive pattern 2c can be considerably improved.

### Third Embodiment

A heat dissipation circuit board 21 illustrated in FIG. 5 mainly includes a flexible printed circuit board 2 including an insulating film (base film) 2a disposed at a back surface and a conductive pattern 2c having a plurality of land parts 2b and disposed at a front surface, a light emitting diode 3 mounted on the plurality of land parts 2b, an adhesive layer 4 stacked on the back surface of the insulating film (base film) 2a, and a supporting member (metal plate) 7 stacked on the back surface of the adhesive layer 4. In a first region A that covers at least projection regions of the plurality of land parts 2b for the light emitting diode 3, the insulating film 2 and the adhesive layer 4 are removed. The removed portions of the insulating film (base film) 2a and the adhesive layer 4 are filled with a thermally conductive adhesive 5. The flexible printed circuit board 2 also includes a through-hole 8 in the first region A, and at least a portion on the back surface side of the through-hole 8 is also filled with the thermally conductive adhesive 5. The flexible printed circuit board 2, the light emitting diode 3, the adhesive layer 4, the thermally conductive adhesive 5, and the supporting member (metal plate) 7 are the same as those included in the heat dissipation circuit board 11 according to the second embodiment, and therefore the same reference numerals are given to omit the description.

### (Through-Hole)

The through-hole 8 is formed in the first region A and penetrates the coverlay 2d and a region other than the land parts 2b of the conductive pattern 2c of the flexible printed circuit board 2. At least a portion on the back surface side of the through-hole 8 is filled with the thermally conductive adhesive 5. As illustrated in FIG. 5, the through-hole 8 and a portion above the through-hole 8 are also preferably filled with the thermally conductive adhesive 5 so that the thermally conductive adhesive 5 contacts the back surface of the light emitting diode 3. By bringing the thermally conductive adhesive 5 into contact with the back surface of the light emitting diode 3, the heat dissipation effect of the light emitting diode 3 can be further improved.

In FIG. 5, only one through-hole 8 is formed, but a plurality of through-holes 8 may be formed in a single first region A.

The lower limit of the average area of the through-hole 8 is preferably 0.005 mm² and more preferably 0.01 mm². The upper limit of the average area of the through-hole 8 is preferably 1 mm² and more preferably 0.5 mm². If the average area of the through-hole 8 is less than the lower limit, an effect of preventing the leakage of the thermally conductive adhesive 5 and an improvement in the heat dissipation effect may be insufficient. If the average area of the through-hole 8 is more than the upper limit, the strength of the flexible printed circuit board 2 may decrease.

The through-hole 8 may be formed before or after the insulating film (base film) 2a is removed in the first region A or may be formed simultaneously with the removal. The through-hole 8 may be formed by the same method as the method for removing the insulating film (base film) 2a.

### <Advantage>

The heat dissipation circuit board 21 includes the through-hole 8. This can prevent the thermally conductive adhesive 5 from leaking out to a region outside the first region A during the filling with the thermally conductive adhesive 5. When the through-hole 8 and a portion above the through-hole 8 are filled with the thermally conductive adhesive 5 so that the thermally conductive adhesive 5 contacts the back surface of the light emitting diode 3, the heat dissipation effect of the light emitting diode 3 can be further improved.

### Fourth Embodiment

A heat dissipation circuit board 31 illustrated in FIG. 6 mainly includes a flexible printed circuit board 2 including an insulating film (base film) 2a disposed at a back surface and a conductive pattern 2c having a plurality of land parts 2b and disposed at a front surface, a plurality of light emitting diodes 3 mounted on the plurality of land parts 2b, an adhesive layer 4 stacked on the back surface of the insulating film (base film) 2a, and a supporting member (metal plate) 37 disposed (stacked) on the back surface of the adhesive layer 4. In a plurality of first regions A that cover at least projection regions of the plurality of land parts 2b for each of the light emitting diodes 3, the insulating film (base film) 2a and the adhesive layer 4 are removed. The removed portions of the insulating film (base film) 2a and the adhesive layer 4 are filled with a thermally conductive adhesive 5. The flexible printed circuit board 2, the light emitting diode 3, the adhesive layer 4, and the thermally conductive adhesive 5 are the same as those included in the heat dissipation circuit board 1 according to the first embodiment, except that the plurality of light emitting diodes 3 are mounted on the flexible printed circuit board 2 and the plurality of first regions A are formed. Therefore, the same reference numerals are given to omit the description.

### <Supporting Member (Metal Plate)>

The supporting member (metal plate) 37 is a plate-shaped member made of a metal, and has a curved surface or a bent surface in a stacking region of the flexible printed circuit board 2. Specifically, the supporting member (metal plate) 37 is curved or bent so that the stacking surface of the flexible printed circuit board 2 protrudes. Therefore, the flexible printed circuit board 2 is curved or bent along the front surface of the supporting member (metal plate) 37. When the supporting member (metal plate) 37 is curved or bent in such a manner, the emission directions of the plurality of light emitting diodes 3 mounted on the flexible printed circuit board 2 can be differentiated. For example, this can decrease a variation in light intensity at relative positions from an LED lighting apparatus that uses the heat dissipation circuit board 31.

The material and average thickness of the supporting member (metal plate) 37 may be the same as those of the supporting member (metal plate) 7 of the heat dissipation circuit board 11 according to the second embodiment.

The light emitting diodes 3 are preferably mounted on a surface other than the curved surface and bent surface of the supporting member (metal plate) 37 and the flexible printed circuit board 2 in terms of connection reliability. In FIG. 6, three light emitting diodes 3 are illustrated, but the number of the light emitting diodes 3 mounted in the heat dissipation circuit board 31 is not limited to three, and may be 2 or 4 or more.

### <Advantage>

In the heat dissipation circuit board 31, the flexible printed circuit board 2 is disposed (stacked) on the supporting member (metal plate) 37 with the insulating film (base film) 2a disposed therebetween in a region other than the first region A. Therefore, even if the heat dissipation circuit board 31 is curved along the supporting member (metal plate) 37 having a curved surface or a bent surface, the insulating property is not easily degraded. Thus, the heat dissipation circuit board 31 can maintain the insulation reliability, and supporting members (metal plates) 37 having various shapes can be employed.

### Fifth Embodiment

In a heat dissipation circuit board according to an embodiment of the present invention, the removed portions of an insulating film and an adhesive layer of at least two adjacent electronic components are preferably continuously present. That is, a thermally conductive adhesive with which the removed portions of an insulating film and an adhesive layer of at least two adjacent electronic components are preferably continuously disposed. Furthermore, when three or more electronic components are present, all the removed portions of the insulating film and the adhesive layer may be continuously present. Alternatively, the removed portions of the insulating film and the adhesive layer of any adjacent electronic components may be continuously present.

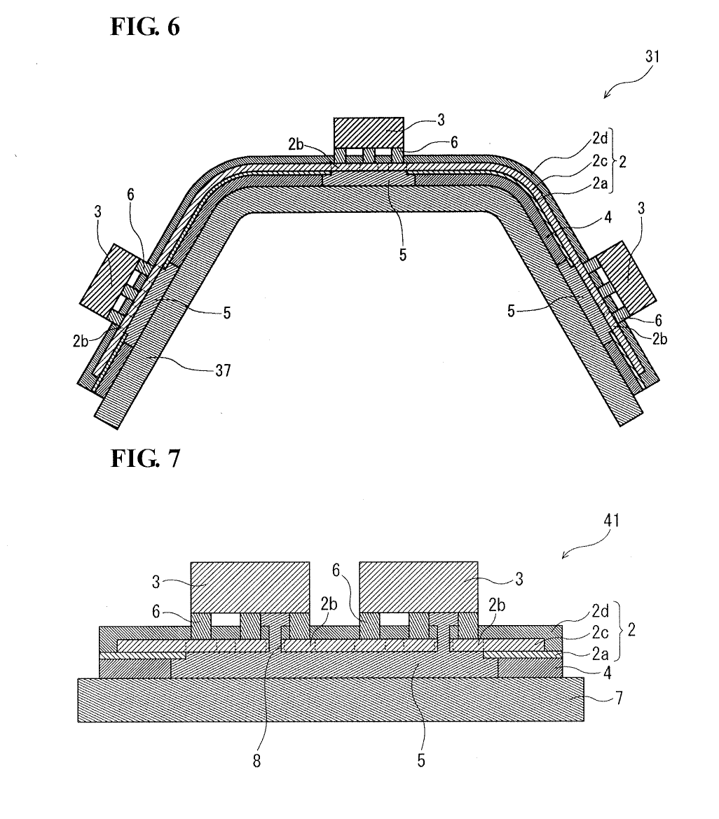

A heat dissipation circuit board 41 illustrated in FIG. 7 includes a flexible printed circuit board 2 including an insulating film (base film) 2a disposed at a back surface and a conductive pattern 2c having a plurality of land parts 2b and disposed at a front surface, a plurality of light emitting diodes 3 mounted on the plurality of land parts 2b so as to be adjacent to each other, an adhesive layer 4 stacked on the back surface of the insulating film (base film) 2a, and a supporting member (metal plate) 7 disposed (stacked) on the back surface of the adhesive layer 4. In a plurality of first regions A that cover at least projection regions of the plurality of land parts 2b for each of the light emitting diodes 3, the insulating film (base film) 2a and the adhesive layer 4 are removed. The removed portions of the insulating film (base film) 2a and the adhesive layer 4 are filled with a thermally conductive adhesive 5. Furthermore, the removed portions of the insulating film (base film) 2a and the adhesive layer 4 of the adjacent light emitting diodes 3 are continuously present.

The flexible printed circuit board 2, the light emitting diode 3, the adhesive layer 4, the thermally conductive adhesive 5, and the supporting member (metal plate) 7 are the same as those included in the heat dissipation circuit board 1 according to the third embodiment, except that the plurality of light emitting diodes 3 are mounted on the flexible printed circuit board 2 so as to be adjacent to each other, the plurality of first regions A are formed, the removed portions of the insulating film (base film) 2a and the adhesive layer 4 are continuously present, and the thermally conductive adhesive 5 is continuously disposed. Therefore, the same reference numerals are given to omit the description.

### <Advantage>

In the heat dissipation circuit board 41, the removed portions of the insulating film (base film) 2a and the adhesive layer 4 are continuously present, and thus the number of filling processes with the thermally conductive adhesive 5 can be decreased. Therefore, the production process of the heat dissipation circuit board 41 is simplified. Even if a large number of light emitting diodes 3 are densely disposed, the heat dissipation effect of the heat dissipation circuit board 41 is excellent due to the thermally conductive adhesive 5. Furthermore, although a relatively large amount of the thermally conductive adhesive 5 is used in the heat dissipation circuit board 41, a good insulating property is achieved without increasing the thickness of the thermally conductive adhesive 5 because the adhesive layer 4 is present around the thermally conductive adhesive 5.

### Other Embodiments

It should be noted that the embodiments disclosed herein are illustrative and not restrictive in all points. The scope of the present invention is not limited to the structures in the above embodiments and is indicated by claims, and is intended to embrace all the modifications within the meaning and scope of equivalency of the claims.

In the first embodiment, the second embodiment, and the third embodiment, the number of light emitting diodes mounted is one, but two or more light emitting diodes may be mounted. In the fourth embodiment, one light emitting diode may be mounted.

In the above embodiments, the light emitting diode is mounted on the printed circuit board, but an electronic component other than the light emitting diode may be mounted on the printed circuit board. The number of the land parts on which one electronic component is mounted is not limited to two or more and may be one.

In the above embodiments, the adhesive layer is removed in the second region that covers the first region, and the resulting removed portion is filled with the thermally conductive adhesive. However, the adhesive layer may be removed only in the first region as in the case of the insulating film (base film), and the resulting removed portion may be filled with the thermally conductive adhesive. That is, the first region and the second region may be the same (may have the same area).

In the above embodiments, the first region is a region that includes all the projection regions of the land parts for each electronic component, but the first region may be divided into projection regions of the plurality of land parts. Furthermore, the first region may include a region that does not overlap the projection region of the electronic component.

In the above embodiments, a metal plate is used as the supporting member, but the material for the supporting member is not limited to a metal. For example, the supporting member may be made of ceramic. The ceramic used for the supporting member preferably has a good insulating property (i.e., low electrical conductivity) and high thermal conductivity. Examples of the ceramic used for the supporting member include aluminum nitride (AlN), aluminum oxide (Al₂O₃), and silicon nitride (Al₃N₄). When the supporting member is made of ceramic having a good insulating property and high thermal conductivity, there is substantially no potential of short circuits between the heat dissipation circuit board and a substrate on which the heat dissipation circuit board is disposed. This can considerably decrease the thickness of the thermally conductive adhesive, and thus the heat dissipation of the heat dissipation circuit board can be improved. Furthermore, when the supporting member is made of ceramic, the withstanding voltage of the heat dissipation circuit board is improved.

In the above embodiments, a plate-shaped member is used as the supporting member, but the shape of the supporting member is not limited thereto. For example, the supporting member may be a bulk having a curved surface or corners. The shape of the supporting member may be a prism, a cone, a trapezoidal prism, or the like or may be a shape formed by chamfering or rounding the corners of the foregoing shapes. When the supporting member has such a shape, the number of paths through which heat is conducted is increased. This can effectively suppress an excess increase in temperature of the light emitting diode or the like. Even if the supporting member is made of a material (e.g., ceramic) with poor flexibility, there is no need to curve or bend the supporting member and thus a three-dimensional heat dissipation circuit board can be easily produced. The supporting member may include cavities therein to decrease the weight of the supporting member.

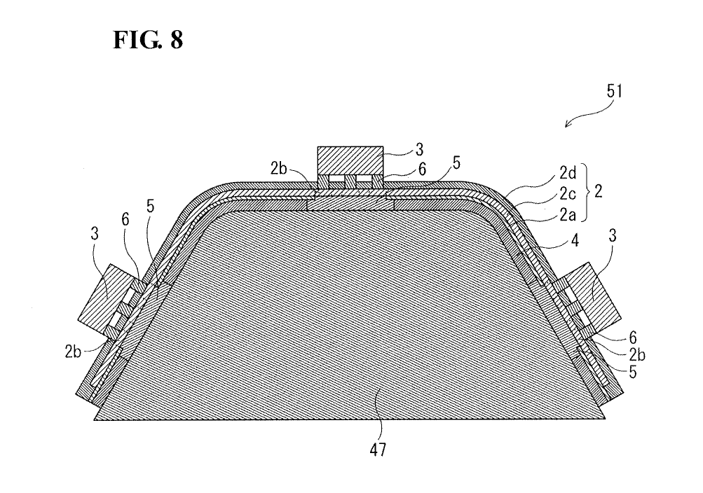

A heat dissipation circuit board 51 illustrated in FIG. 8 is the same as the heat dissipation circuit board 31 in the fourth embodiment, except that the sectional shape of a supporting member 47 is a trapezoid. When the supporting member 47 has such a shape, there is no need to curve or bend the supporting member 47. Consequently, the production process of the heat dissipation circuit board 51 is simplified.

In the third embodiment, when the insulating film (base film)-removing step is performed and then the light emitting diode-mounting step is performed, the insulating film (base film)-removing step may be a step described below.

First, an insulating film (base film) 2a is prepared which has a portion removed in advance in a first region A that covers at least regions to be projection regions of a plurality of land parts 2b when a light emitting diode 3 is mounted. Next, a base material having conductivity, such as copper, is stacked on the insulating film (base film) 2a. Subsequently, the base material is patterned to form a conductive pattern 2c. Then, a coverlay 2d is stacked in a portion other than a portion (the front surface side of the land parts 2b) of the front surface of the flexible printed circuit board 2 on which the light emitting diode 3 is to be mounted.

Thus, a flexible printed circuit board similar to the flexible printed circuit board produced in the insulating film (base film)-removing step of the third embodiment can also be produced through the above step.

Moreover, the printed circuit boards used in embodiments of the present invention are not limited to flexible printed circuit boards having flexibility and may be rigid printed circuit boards. The printed circuit boards used in embodiments of the present invention are not limited to those used in the above embodiments as long as the land parts are present at a front surface and the insulating film (base film) is disposed at a back surface. The printed circuit board may be, for example, a double-sided printed circuit board in which a conductive pattern is formed on both surfaces of an insulating film or a multilayer printed circuit board in which a plurality of insulating films each having a conductive pattern are stacked. In the case of such a double-sided printed circuit board or a multilayer printed circuit board, the heat dissipation effect can be improved by bringing the thermally conductive adhesive into contact with the conductive pattern on the backmost surface side (on the side opposite to the side of the surface on which the electronic component is mounted).

### EXAMPLES

Hereafter, the present invention will be further specifically described based on Examples, but the present invention is not limited to Examples below.

### [No. 1]

A flexible printed circuit board is prepared in which an insulating film (base film) mainly made of polyimide and having an average thickness of 25 μm, a conductive pattern made of a copper foil and having an average thickness of 35 μm, and a coverlay including an insulating layer mainly made of polyimide and having an average thickness of 25 μm and an adhesive layer having an average thickness of 30 μm are stacked from the back surface side in that order. The flexible printed circuit board has a white coat on its front surface (front surface of the coverlay). The flexible printed circuit board also has land parts that allow an LED (light emitting diode) to be mounted on the conductive pattern, and holes are formed in the coverlay along the land parts.

Subsequently, the insulating film (base film) is removed using an etching solution in a projection region (having an area equal to the plane area of the LED) of a region of the flexible printed circuit board on which the LED is to be mounted. Thus, the conductive pattern is exposed. Then, lead-free solder (Sn-3.0Ag-0.5Cu) is applied onto the land parts by screen printing using a metal mask having a thickness of 150 μm. A white LED (“NS6W833T” manufactured by NICHIA Corporation) is placed on the solder, and the LED is mounted by reflowing the solder.

Subsequently, the surface of a polyethylene terephthalate film (release film) subjected to a release treatment is coated with an epoxy adhesive, and the adhesive is dried so as to be in a B-stage state and have an average thickness of 20 μm. A release film is further stacked on the surface of the adhesive to produce an adhesive sheet. A portion (having an area equal to the plane area of the LED) corresponding to the projection region of an LED-mounted region of the adhesive sheet is cut out while at the same time the adhesive sheet is punched out so as to have the outside shape of the flexible printed circuit board. Then, one of the release films of the adhesive sheet is detached. The adhesive sheet is temporarily attached to the back surface of the flexible printed circuit board so that the cut-out-portion is aligned with the conductive pattern-exposed region of the insulating film (base film).

After the temporary attachment of the adhesive sheet (after the stacking of the adhesive layer), a 200-mesh screen having an opening with a width 50 μm larger than that of the cut-out-portion is placed on the back surface of the adhesive sheet. The cut-out-portion (the removed portions of the insulating film (base film) and the adhesive) is filled, by screen printing, with a thermally conductive adhesive having a thermal conductivity of 3 W/mK and prepared by mixing an epoxy adhesive, a curing agent, and alumina particles having a particle size of 5 to 30 μm and alumina particles having a particle size of 0.5 to 1 μm.

After the filling with the thermally conductive adhesive, the release film on the back surface of the adhesive sheet is detached, and the adhesive sheet is temporarily attached to a metal plate serving as a supporting member. The resulting layered body is heated to 100° C. in a vacuum container to decrease the viscosity of the adhesive, and then a pressure of 0.1 MPa is applied using a silicone rubber from the front surface side of the LED-mounted flexible printed circuit board to perform temporary compression bonding. Then, the layered body is taken out of the vacuum container, inserted into a pre-heated oven, and heated at 150° C. for 60 minutes to cure the adhesive. Thus, a heat dissipation circuit board of No. 1 is obtained.

### [No. 2]

The same flexible printed circuit board as No. 1 is prepared except that, in the flexible printed circuit board, the average thickness of the insulating film (base film) is changed to 13 μm, the average thickness of the conductive pattern is changed to 18 μm, the average thickness of the insulating layer of the coverlay is changed to 13 μm, and the average thickness of the adhesive layer of the coverlay is changed to 20 μm; and the projection region of a region of the insulating film (base film) on which an LED is to be mounted is removed by using laser beams instead of the etching solution. An LED is mounted through the same process as No. 1, except that a metal mask having a thickness of 100 μm is used for the flexible printed circuit board. Furthermore, the same adhesive sheet (having a cut-out-portion) as No. 1 is prepared.

Subsequently, a release film is coated with a thermally conductive adhesive having a thermal conductivity of 4 W/mK and prepared by mixing an epoxy adhesive, an amine-based curing agent, and boron nitride particles having a particle size of 5 to 30 μm and alumina particles having a particle size of 0.1 to 1 μm. The thermally conductive adhesive is dried so as to be in a B-stage state and have an average thickness of 70 μm. The thermally conductive adhesive sheet is half-cut by punching so as to have a shape with a width 100 μm larger than that of the cut-out-portion (having an area equal to the plane area of the LED) of the adhesive sheet while the release sheet is left.

Subsequently, the thermally conductive adhesive sheet is attached to the removed portion (exposed portion of the conductive pattern) of the insulating film (base film) of the flexible printed circuit board. After the attachment of the thermally conductive adhesive sheet, one of the release films of the adhesive sheet is detached. The adhesive sheet is temporarily attached to the back surface of the flexible printed circuit board so that the cut-out-portion is aligned with the conductive pattern-exposed region of the insulating film (base film).

After the adhesive sheet is temporarily attached to the back surface of the flexible printed circuit board, the release films on the back surfaces of the thermally conductive adhesive sheet and the adhesive sheet are detached. The thermally conductive adhesive sheet and the adhesive sheet are temporarily attached to a metal plate serving as a supporting member. The resulting layered body is heated to 100° C. in a vacuum container to decrease the viscosity of the adhesive, and then a pressure of 0.2 MPa is applied using a silicone rubber from the front surface side of the LED-mounted flexible printed circuit board to perform temporary compression bonding. Herein, the viscosity of the thermally conductive adhesive decreases and the thermally conductive adhesive flows due to the pressurization. As a result, the removed portions of the insulating film (base film) and the adhesive are filled with the thermally conductive adhesive, and the thermally conductive adhesive contacts the conductive pattern. Then, the layered body is taken out of the vacuum container, inserted into a pre-heated oven, and heated at 150° C. for 60 minutes to cure the adhesive. Thus, a heat dissipation circuit board of No. 2 is obtained.

### [No. 3]

The same LED-mounted flexible printed circuit board and adhesive sheet (having a cut-out-portion) as No. 1 are prepared, and the adhesive sheet is temporarily attached to the back surface of the flexible printed circuit board through the same process as No. 1.

After the adhesive sheet is temporarily attached, the same thermally conductive adhesive as No. 1 is ejected to the cut-out-portion of the adhesive sheet using a dispenser and left to stand in the atmospheric environment for 30 minutes to planarize the surface. Thus, the removed portions of the insulating film (base film) and the adhesive are filled with the thermally conductive adhesive.

After the filling with the thermally conductive adhesive, the release film on the back surface of the adhesive sheet is detached, and the adhesive sheet is temporarily attached to a metal plate serving as a supporting member. The resulting layered body is heated to 100° C. in a vacuum container to decrease the viscosity of the adhesive, and then a pressure of 0.1 MPa is applied using a silicone rubber from the front surface side of the LED-mounted flexible printed circuit board to perform temporary compression bonding. Then, the layered body is taken out of the vacuum container, inserted into a pre-heated oven, and heated at 150° C. for 60 minutes to cure the adhesive. Thus, a heat dissipation circuit board of No. 3 is obtained.

### [No. 4]

The same LED-mounted flexible printed circuit board as No. 1 is prepared. Then, the surface of the release film is coated with an epoxy adhesive, and the adhesive is dried so as to be in a B-stage state and have an average thickness of 20 μm. A release film is further stacked on the surface of the adhesive to produce an adhesive sheet. The adhesive sheet is punched out so as to have the outside shape of the flexible printed circuit board without cutting out a portion corresponding to the projection region of an LED-mounted region of the adhesive sheet. Then, one of the release films of the adhesive sheet is detached, and the adhesive sheet is temporarily attached to the back surface of the flexible printed circuit board.

After the adhesive sheet is temporarily attached, the release film on the back surface of the adhesive sheet is detached. The adhesive sheet is temporarily attached to a metal plate serving as a supporting member. The resulting layered body is heated to 100° C. in a vacuum container to decrease the viscosity of the adhesive, and then a pressure of 0.1 MPa is applied using a silicone rubber from the front surface side of the LED-mounted flexible printed circuit board to perform temporary compression bonding. Then, the layered body is taken out of the vacuum container, inserted into a pre-heated oven, and heated at 150° C. for 60 minutes to cure the adhesive. Thus, a heat dissipation circuit board of No. 4 is obtained.

### Reference Example

A printed circuit board is prepared in which a conductive pattern made of a copper foil and having an average thickness of 35 μm is stacked on a base material made of aluminum and having an average thickness of 1 mm with a thermally conductive adhesive disposed therebetween, the thermally conductive adhesive having a thermal conductivity of 3 W/mK and an average thickness of 80 μm. The printed circuit board includes land parts in the conductive pattern on which an LED can be mounted.

Subsequently, lead-free solder (Sn-3.0Ag-0.5Cu) is applied onto the land parts of the printed circuit board by screen printing using a metal mask having a thickness of 150 μm. A white LED is placed on the solder, and the LED is mounted by reflowing the solder. Thus, a heat dissipation circuit board of Reference Example is obtained.

### [Evaluation]

The following heat dissipation test was performed for the heat dissipation circuit boards of No. 1 to No. 4 and Reference Example. The temperature characteristics of the heat dissipation circuit boards were determined through the following procedure. First, each of the heat dissipation circuit boards is placed in a thermostat oven while a lead is connected. The thermostat oven is kept at 30° C., 40° C., 50° C., and 60° C. for 30 minutes or more each time the temperature of the thermostat oven reaches each of the temperatures in order to stabilize the temperatures of the thermostat oven and the heat dissipation circuit board. At each of the temperatures, a voltage applied when a micro-current (e.g., a current of 4 mA) is caused to flow through the heat dissipation circuit board is measured. A micro-current is employed as the current caused to flow through the heat dissipation circuit board for the purpose of preventing the temperature of the LED from increasing due to self-heating. The obtained relationship between voltage and temperature is linearly approximated by the method of least squares. As a result, the temperature characteristics of the LED are derived to be about −1.4 mV/° C.

Subsequently, the heat dissipation circuit board is left to stand at a place where there is no influence of outside wind so that the heat dissipation circuit board has a room temperature of 23° C. Subsequently, the heat dissipation circuit board is connected to a direct-current power supply through the lead wire. The heat dissipation circuit board is repeatedly subjected to the following operation for a maximum of 30 minutes until the temperature of the LED which increases as the current is caused to flow stabilizes (a constant voltage is obtained): first, a current of 4 mA is caused to flow and the voltage at room temperature is measured; then, a current of 300 mA is caused to flow for 15 seconds, the current is changed to 4 mA within 0.1 seconds, and the voltage is measured; and, again, a current of 300 mA is caused to flow for 15 seconds, the current is changed to 4 mA within 0.1 seconds, and the voltage is measured. The difference between the voltage measured when a current of 4 mA is caused to flow and the temperature has stabilized and the initial voltage measured at room temperature when a current of 4 mA is caused to flow is divided by the temperature characteristics of the LED measured in advance. Thus, an increase in temperature of the LED from the room temperature is derived. Table I shows the results.

TABLE I

| | Increase in temperature |
|---|---|
| | ° C. |
| No. 1 | 32.1 |
| No. 2 | 31.7 |
| No. 3 | 32.0 |
| No. 4 | 41.5 |
| Reference Example | 31.9 |

As shown in Table I, the heat dissipation circuit boards of No. 1 to No. 3 produce the same heat dissipation effect as the heat dissipation circuit board in Reference Example that uses aluminum as a base material.

### INDUSTRIAL APPLICABILITY

As described above, the heat dissipation circuit board and the production method according to the present invention can provide a circuit board that has high insulation reliability, can effectively facilitate the heat dissipation of electronic components mounted, and is suitably used for LED lighting devices and the like.

### REFERENCE SIGNS LIST

1, 11, 21, 31, 41, 51 heat dissipation circuit board
2 flexible printed circuit board
2a insulating film (base film)
2b land part
2c conductive pattern
2d coverlay
3 light emitting diode
4 adhesive layer
5 thermally conductive adhesive
6 solder
7, 37 supporting member (metal plate)
8 through-hole
12 coat layer
47 supporting member

1. A heat dissipation circuit board comprising:
a printed circuit board including an insulating film disposed at a back surface and one or more land parts disposed at a front surface;
one or more electronic components mounted on the one or more land parts; and
an adhesive layer stacked on a back surface of the insulating film,
wherein the insulating film and the adhesive layer are removed in a first region that covers at least projection regions of the one or more land parts for each of the electronic components, and
removed portions of the insulating film and the adhesive layer are filled with a thermally conductive adhesive.

2. The heat dissipation circuit board according to claim 1, wherein the first region overlaps projection regions of the electronic components disposed in the first region, and an area occupied by the first region is twice or less a projection area of the electronic components disposed in the first region.

3. The heat dissipation circuit board according to claim 1, wherein the adhesive layer is further removed in a second region that covers the first region.

4. The heat dissipation circuit board according to claim 2, wherein the printed circuit board has a through-hole in each first region, and at least a portion on the back surface side of the through-hole is also filled with the thermally conductive adhesive.

5. The heat dissipation circuit board according to claim 4, wherein the through-hole and a portion above the through-hole are also filled with the thermally conductive adhesive so that the thermally conductive adhesive contacts a back surface of each of the electronic components.

6. The heat dissipation circuit board according to claim 1, wherein the printed circuit board has flexibility.

7. The heat dissipation circuit board according to claim 1, wherein a main component of the insulating film is polyimide, a liquid crystal polymer, a fluororesin, polyethylene terephthalate, or polyethylene naphthalate.

8. The heat dissipation circuit board according to claim 1, wherein the thermally conductive adhesive has a thermal conductivity of 1 W/mK or more.

9. The heat dissipation circuit board according to claim 1, wherein each of the electronic components is a light emitting diode.

10. The heat dissipation circuit board according to claim 9, wherein a surface of the printed circuit board has a light reflecting function.

11. The heat dissipation circuit board according to claim 1, comprising a supporting member disposed on a back surface of the adhesive layer.

12. The heat dissipation circuit board according to claim 11, wherein the supporting member has a curved surface or a bent surface in a stacking region of the printed circuit board.

13. A method for producing a heat dissipation circuit board including a printed circuit board including an insulating film disposed at a back surface and one or more land parts disposed at a front surface, one or more electronic components mounted on the one or more land parts, an adhesive layer stacked on a back surface of the insulating film, and a supporting member disposed on a back surface of the adhesive layer, the method comprising:
a step of mounting the one or more electronic components on the one or more land parts;
a step of removing the insulating film in a first region that covers at least projection regions of the one or more land parts for each of the electronic components;
a step of stacking, on the back surface of the insulating film, the adhesive layer in which at least a portion corresponding to the first region has been removed;
a step of filling removed portions of the insulating film and the adhesive layer with a thermally conductive adhesive; and
a step of disposing a supporting member on the back surface of the adhesive layer having the removed portion filled with the thermally conductive adhesive.
